(19) United States
(12) Patent Application Publication
(10) Pub. No.: US 2026/0271271 A1
(43) Pub. Date: Sep. 10, 2026

(54) SEMICONDUCTOR STRUCTURE AND METHOD FOR FORMING SAME

(71) Applicant: CXMT Corporation, Hefei (CN)

(72) Inventors: Yang Hu, Hefei (CN); Guoquan Liu, Hefei (CN); Xiaopeng Wu, Hefei (CN); Hui Lyu, Hefei (CN); Zhengtao Tang, Hefei (CN); Hongyun Qian, Hefei (CN)

(73) Assignee: CXMT Corporation, Hefei (CN)

(21) Appl. No.: 19/425,071

(22) Filed: Dec. 18, 2025

Related U.S. Application Data
(63) Continuation of application No. PCT/CN2025/131565, filed on Oct. 31, 2025.

(30) Foreign Application Priority Data
Mar. 5, 2025 (CN) 202510259590.8

(51) Int. Cl. H10B 12/00; H10D 1/68

(52) U.S. Cl. CPC H10B 12/33; H10B 12/036; H10B 12/05; H10D 1/716

(57) ABSTRACT

Embodiments of the present disclosure provide a semiconductor structure and a method for manufacturing the same. The semiconductor structure includes: a substrate provided with a device region, a first isolation region, and a second isolation region disposed between the device region and the first isolation region. The second isolation region is further provided with a first semiconductor material region adjacent to the first isolation region. In the semiconductor structure according to the embodiments of the present disclosure, by retaining a portion of the semiconductor material region in the isolation region adjacent to the device region, dimensional variations between the device region and the isolation region caused by differences in pattern density are compensated

### CROSS-REFERENCE TO RELATED APPLICATIONS

The present application is a continuation of International Patent Application No. PCT/CN2025/131565, filed on Oct. 31, 2025, which claims priority to Chinese Patent Application No. 202510259590.8 filed with China National Intellectual Property Administration on Mar. 05, 2025 and entitled “SEMICONDUCTOR STRUCTURE AND METHOD FOR FORMING SAME”, the content of which is incorporated herein by reference in its entirety.

### TECHNICAL FIELD

Embodiments of the present disclosure relate to the technical field of semiconductors, and particularly, to a semiconductor structure and a method for forming the same.

### BACKGROUND

Dynamic random access memory (DRAM) is widely used for data storage. The DRAM includes a plurality of memory cells composed of transistors and capacitors. The memory cells are arranged in an array, where word lines extend along rows of the array, while bit lines extend along columns of the array. The word lines can be coupled to the transistors in the memory cells. Each memory cell can be uniquely addressed by a combination of one of the word lines and one of the bit lines.

As the integration level of semiconductor devices increases and manufacturing processes are constantly updated, the interplay between various process steps has become increasingly important to the product yield.

### SUMMARY

Embodiments of the present disclosure provide a semiconductor structure with a higher yield and a method for forming the same.

The problems to be solved by the technical spirit of the present disclosure are not limited to the above-mentioned problems, and those skilled in the art will clearly understand other unmentioned problems from the following description.

Some embodiments of the present disclosure provide a semiconductor structure. The semiconductor structure includes: a substrate, a first isolation region, and a second isolation region. The substrate is provided with a device region. The second isolation region is disposed between the device region and the first isolation region; the second isolation region is further provided with a first semiconductor material region, and the first semiconductor material region is disposed adjacent to the first isolation region.

In the semiconductor structure according to the embodiments of the present disclosure, the device region includes a plurality of second semiconductor material regions spaced apart, first conductive structures disposed corresponding to the plurality of second semiconductor material regions, and an isolation structure isolating the first conductive structures, and in a direction perpendicular to the substrate, an extension depth of the isolation structure is less than an extension depth of the first isolation region or an extension depth of the second isolation region, and the extension depth of the second isolation region is not greater than the extension depth of the first isolation region.

In the semiconductor structure according to the embodiments of the present disclosure, the device region further includes second conductive structures, the second conductive structures are disposed corresponding to the plurality of second semiconductor material regions, the isolation structure is further disposed between the first conductive structures and the second conductive structures, and the second conductive structures are connected to corresponding second semiconductor material regions.

In the semiconductor structure according to the embodiments of the present disclosure, a surface of each second conductive structure in the device region is not lower than surfaces of the first isolation region and the second isolation region.

In the semiconductor structure according to the embodiments of the present disclosure, the first isolation region includes at least one isolation material, the second isolation region includes at least two isolation materials, and at least one of the at least two isolation materials in the second isolation region is different from the at least one isolation material in the first isolation region.

In the semiconductor structure according to the embodiments of the present disclosure, at least one surface of the first semiconductor material region is not exposed by a surface of the second isolation region.

In the semiconductor structure according to the embodiments of the present disclosure, the isolation structure includes at least two isolation materials, each of the at least two isolation materials in the isolation structure is the same as an isolation material in the second isolation region, and at least one of the at least two isolation materials in the isolation structure is different from an isolation material in the first isolation region.

The embodiments of the present disclosure further provide a method for forming a semiconductor structure. The method includes: providing a substrate, and patterning the substrate to form a first isolation region in the substrate; and patterning the substrate to form a device region and a second isolation region in the substrate, the second isolation region being disposed between the device region and the first isolation region, where when the substrate is patterned to form the second isolation region, a portion of the substrate located in the second isolation region is retained to form a first semiconductor material region, and the first semiconductor material region is disposed adjacent to the first isolation region.

In the method for forming the semiconductor structure according to the embodiments of the present disclosure, the substrate is provided with a first surface and a second surface, and the first surface is disposed opposite to the second surface; patterning the substrate to form the device region and the second isolation region in the substrate includes: patterning the first surface of the substrate to form a plurality of first trenches and a second trench in the substrate, the substrate being divided by the plurality of first trenches to form a plurality of second semiconductor material regions spaced apart; filling the plurality of first trenches and the second trench to form an isolation structure in the first trenches, and to form the second isolation region in the second trench; and forming first conductive structures between the isolation structure and the plurality of second semiconductor material regions, the first conductive structures, the plurality of second semiconductor material regions, and the isolation structure forming the device region, where in a direction perpendicular to the substrate, an extension depth of the isolation structure is less than an extension depth of the second isolation region or an extension depth of the first isolation region, and the extension depth of the second isolation region is not greater than the extension depth of the first isolation region.

The method for forming the semiconductor structure according to the embodiments of the present disclosure further includes forming second conductive structures in the device region, which includes:

thinning the second surface of the substrate, such that a portion of the substrate in the device region is retained and the substrate in the first isolation region and the second isolation region is removed; and forming the second conductive structures on a surface of the retained substrate in the device region, the second conductive structures being connected to corresponding second semiconductor material regions.

In the method for forming the semiconductor structure according to the embodiments of the present disclosure, during the thinning of the second surface of the substrate, the first isolation region is used as a thinning stop region.

In the method for forming the semiconductor structure according to the embodiments of the present disclosure, during the thinning of the second surface of the substrate, the second isolation region is not thinned, and a surface of the first semiconductor region is exposed by a surface of the second isolation region.

In the semiconductor structure according to the embodiments of the present disclosure, by retaining a portion of the semiconductor material region in the isolation region adjacent to the device region, dimensional variations between the device region and the isolation region caused by differences in pattern density are compensated, thereby achieving a semiconductor structure with higher yield.

### BRIEF DESCRIPTION OF DRAWINGS

The drawings, which are incorporated in and constitute a part of this specification, illustrate embodiments consistent with the embodiments of the present disclosure and, together with the specification, serve to explain the principles of the embodiments of the present disclosure.

FIG. 1 is a schematic flowchart of a method for forming a semiconductor structure according to an embodiment of the present disclosure;

FIG. 2 is a top view of a semiconductor structure corresponding to a process of forming the semiconductor structure;

FIG. 3 is a schematic cross-sectional view of a semiconductor structure according to an embodiment of the present disclosure;

FIG. 4 is a top view of a semiconductor structure corresponding to a process of forming the semiconductor structure;

FIG. 5 is a schematic cross-sectional view of a semiconductor structure according to an embodiment of the present disclosure;

FIG. 6 is a top view of a semiconductor structure corresponding to a process of forming the semiconductor structure;

FIG. 7 is a schematic cross-sectional view of a semiconductor structure according to an embodiment of the present disclosure;

FIG. 8 is a schematic cross-sectional view of a semiconductor structure according to an embodiment of the present disclosure;

FIG. 9 is a schematic cross-sectional view of a semiconductor structure according to an embodiment of the present disclosure;

FIG. 10 is a schematic cross-sectional view of a semiconductor structure according to an embodiment of the present disclosure;

FIG. 11 is a schematic cross-sectional view of a semiconductor structure according to an embodiment of the present disclosure;

FIG. 12 is a schematic cross-sectional view of a semiconductor structure according to an embodiment of the present disclosure; and

FIG. 13 is a schematic cross-sectional view of a semiconductor structure according to an embodiment of the present disclosure.

Through the above drawings, explicit embodiments of the embodiments of the present disclosure have been illustrated, and more detailed descriptions will follow. These drawings and textual descriptions are not intended to limit the scope of the inventive concept of the embodiments of the present disclosure in any way, but rather to explain the concepts of the embodiments of the present disclosure to those skilled in the art by referring to specific embodiments.

### DESCRIPTION OF EMBODIMENTS

The technical solutions in the embodiments of the present disclosure will be clearly and completely described hereinafter with reference to the drawings in the embodiments of the present disclosure. It can be understood that the specific embodiments described herein are merely illustrative of the related disclosures and are not intended to limit the present disclosure. In addition, it should be further noted that for the convenience of description, only the relevant portions are shown in the drawings. Unless otherwise defined, all technical and scientific terms used herein have the same meaning as commonly understood by those skilled in the art to which the present disclosure belongs. The terms used herein are for the purpose of describing the embodiments of the present disclosure only and are not intended to limit the present disclosure. In the following description, reference is made to “some embodiments”, which describe subsets of all possible embodiments, but it can be understood that “some embodiments” may be the same subset or different subsets of all possible embodiments, and may be combined with each other without conflict. It should be noted that the terms “first\second\third” referred to in the embodiments of the present disclosure are merely used for distinguishing similar objects and do not represent a specific ordering for the objects.

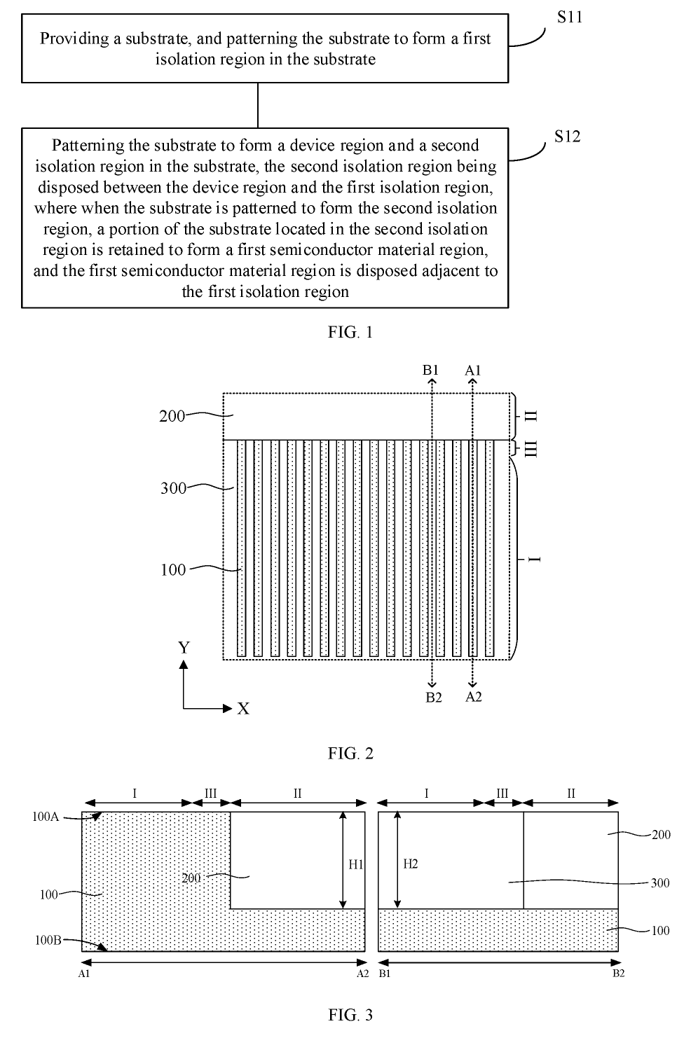

FIG. 1 shows a schematic flowchart of forming a semiconductor structure according to some embodiments. A corresponding method for forming a semiconductor structure includes the following steps.

In S11, a substrate is provided, and the substrate is patterned to form a first isolation region in the substrate.

In S12, the substrate is patterned to form a device region and a second isolation region in the substrate. The second isolation region is disposed between the device region and the first isolation region. When the substrate is patterned to form the second isolation region, a portion of the substrate located in the second isolation region is retained to form a first semiconductor material region, and the first semiconductor material region is disposed adjacent to the first isolation region.

The method for forming the semiconductor structure according to the embodiments of the present disclosure is described in detail below with reference to the corresponding drawings.

First, S11 is performed. Referring to FIGS. 2 and 3, FIG. 2 is a schematic top view of a semiconductor structure according to some embodiments of the present disclosure, and FIG. 3 is a schematic cross-sectional view of a semiconductor structure according to some embodiments of the present disclosure. The semiconductor structure provided in step S11 includes a substrate 100.

The substrate 100 is provided with a first isolation region 200. The first isolation region 200 disposed in the substrate 100 is mainly configured to separate the substrate 100, so as to divide the substrate 100 into an electrical region and an isolation region. As shown in FIGS. 2 and 3, the substrate 100 may be divided into a device region I and an isolation region II. The device region I is an electrical region composed of a plurality of substrates 100 extending in a Y direction and isolated from each other in an X direction, the substrates 100 in the device region I provide active regions for the subsequent formation of semiconductor devices, and the spaced substrates 100 in the device region I are isolated from each other by a first dielectric layer 300. The isolation region II is an isolation region including the substrate 100, and the first isolation region 200 is disposed on the substrate 100 of the isolation region II. FIG. 3 illustrates schematic views of cross-sectional structures taken along the line A1-A2 and the line B1-B2 in FIG. 2, respectively. The line A1-A2 and the line B1-B2 are each parallel to the Y direction, and the X direction and the Y direction are perpendicular to each other. The line A1–A2, extending in the Y direction, is a schematic line virtually set at a cross-sectional position in the substrate 100, and the line B1–B2, extending in the Y direction, is a schematic line virtually set at a cross-sectional position between adjacent substrates 100.

In some embodiments, the step of patterning the substrate 100 to form the first isolation region 200 in the substrate 100 may be performed by depositing a mask, defining the mask pattern by photolithography, and etching the mask pattern to transfer the mask pattern into the substrate 100, thereby forming the first isolation region 200.

In some embodiments, the substrate 100 may be made of or may include various types of semiconductor materials, for example, silicon, germanium, Group III–V materials, or other types of suitable materials. In some embodiments, the substrate 100 is made of silicon (doped or undoped). In an alternative embodiment, the substrate 100 is a silicon-on-insulator (SOI) wafer or a silicon carbide wafer. As an alternative, any other suitable semiconductor material may be used for the substrate 100. For example, semiconductor composite materials, such as gallium arsenide (GaAs), indium phosphide (InP), and any suitable ternary semiconductor composite materials or quaternary semiconductor composite materials, such as indium gallium arsenide (InGaAs), may be used. In these embodiments, the substrate 100 may be a thin or ultra-thin substrate or wafer. For example, the thickness of the substrate is in a range of about a few microns to about a few hundred microns, e.g., in a range of about 5 μm to about 100 μm; or the thickness of the substrate is less than about 100 μm or less than about 50 μm.

In some embodiments, the first dielectric layer 300 may be made of a dielectric material, such as silicon oxide, silicon nitride, or silicon carbonitride. The material filled in the first isolation region 200 may be an insulating dielectric material, such as silicon oxide, silicon nitride, and silicon carbonitride, or other types of dielectric materials. In some embodiments, the first dielectric layer 300 and the first isolation region 200 include the same dielectric material.

With continued reference to FIG. 3, in some embodiments, the substrate 100 is provided with a first surface 100A and a second surface 100B disposed opposite to the first surface 100A, the first isolation region 200 extends from the first surface 100A to the second surface 100B, and in this extension direction, the first isolation region 200 is provided with a first extension depth H1, and the first extension depth H1 is not greater than the extension depth of the substrate 100 in the device region I. In some embodiments, the first surface 100A of the substrate 100 in the device region I is coplanar with the surface of the first isolation region 200; that is, the surfaces of the substrate and the first isolation region are flush or substantially flush with each other. In these embodiments, the first dielectric layer 300 also extends in a direction perpendicular to the X direction or the Y direction. In this extension direction, the first dielectric layer 300 is provided with a second extension depth H2 in the device region I, and the second extension depth H2 may be equal to or substantially equal to the first extension depth H1; for example, the difference between the second extension depth and the first extension depth is controlled within 10 nm to 20 nm. The second extension depth H2 may also be less than the first extension depth H1; for example, the difference between the second extension depth and the first extension depth is greater than 20 nm.

S12 is performed to form the device region and the second isolation region. In some embodiments, forming the device region and the second isolation region includes the following steps.

In S121, the first surface of the substrate is patterned to form a plurality of first trenches and a second trench in the substrate. The substrate is divided by the plurality of first trenches to form a plurality of second semiconductor material regions spaced apart.

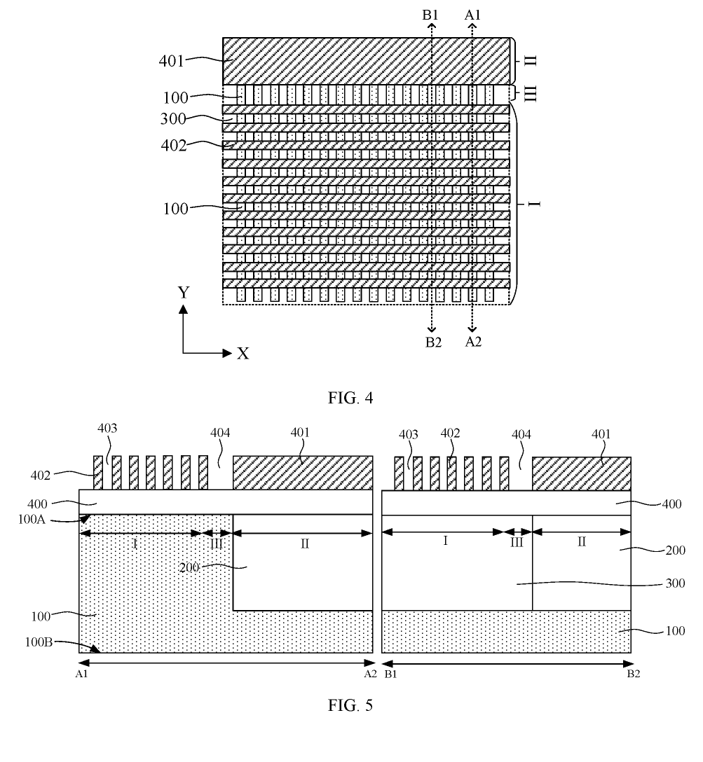

The above step is described in detail below with reference to FIGS. 4 and 5. FIG. 4 is a schematic top view of a semiconductor structure according to some embodiments of the present disclosure, and FIG. 5 is a schematic cross-sectional view of a semiconductor structure according to some embodiments of the present disclosure. Patterning the first surface of the substrate includes: forming a mask layer 400 on the first surface 100A of the substrate 100, where the mask layer 400 further covers the surface of the first isolation region 200. Mask patterns are formed on the mask layer 400. The mask patterns include mask patterns 402 disposed on the device region I and a mask pattern 401 disposed on the first isolation region 200. A plurality of trenches 403 are disposed between the mask patterns 402 on the device region I, and the trenches 403 expose the surface of the mask layer 400. No trench is disposed in the mask pattern 401 on the first isolation region 200; that is, the mask pattern 401 completely covers the mask layer 400 on the first isolation region 200. In some embodiments, a trench 404 is further disposed between the mask pattern 402 and the mask pattern 401, and the mask layer 400 exposed by the trench 404 corresponds to an isolation region III in the substrate 100. FIG. 5 illustrates schematic views of cross-sectional structures taken along the line A1-A2 and the line B1-B2 in FIG. 4, respectively. It can be seen that the mask patterns 402 and the trenches 403 are both formed on the first dielectric layer 300. To more clearly illustrate the corresponding relationship between the mask patterns and the substrate, the mask layer 400 is omitted in FIG. 4.

In some embodiments, the width of the trench 403 is less than the width of the trench 404.

In some embodiments, a plurality of trenches 404 may be formed on the isolation region III, and the number of the trenches 404 on the isolation region III is less than the number of the trenches 403 on the device region I. In the embodiments of the present disclosure, the number of the trenches 404 is illustrated as one, but is not limited thereto.

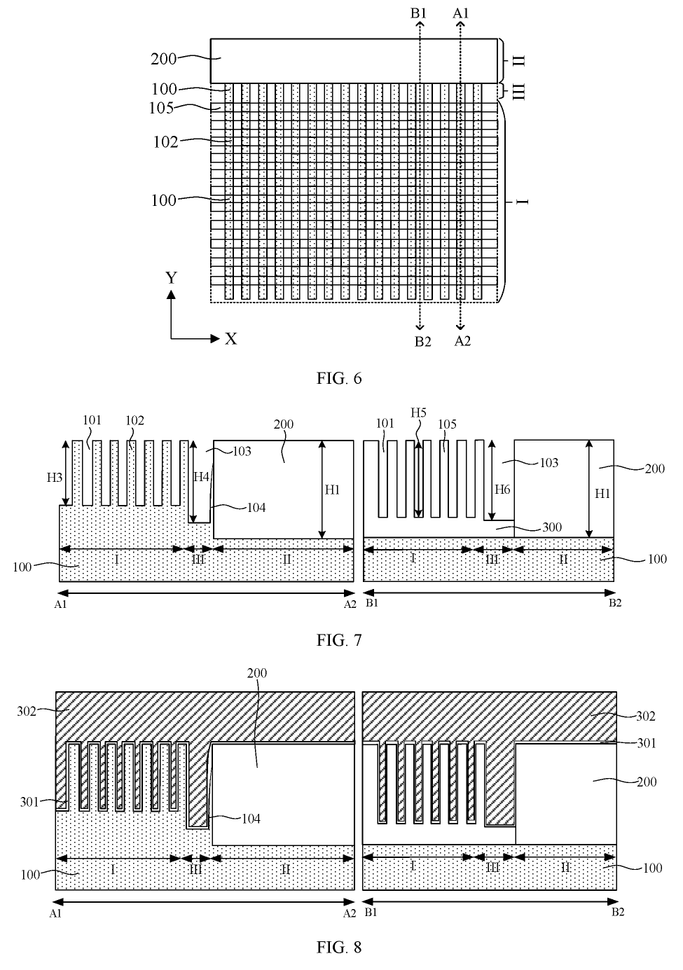

With continued reference to FIGS. 6 and 7, FIG. 6 is a schematic top view of a semiconductor structure according to some embodiments of the present disclosure, and FIG. 7 is a schematic cross-sectional view of a semiconductor structure according to some embodiments of the present disclosure. Upon forming the trenches 403 and the trench 404, the substrate 100 and the first dielectric layer 300 are etched downward along the trenches 403 and the trench 404 by an etching process to form first trenches 101 and a second trench 103 in the substrate 100. In addition, the first trenches 101 and the second trench 103 are both formed in the first dielectric layer 300. In the Y direction, the first trenches 101 divide the substrate 100 in the device region I into a plurality of second semiconductor material regions 102 spaced apart from each other. In addition, the first trenches 101 divide the first dielectric layer 300 into a plurality of dielectric structures 105 spaced apart from each other. Upon forming the first trenches 101 and the second trench 103, the mask layer 400 and the mask patterns thereon are removed.

In some embodiments, the second semiconductor material region 102 has a structure that is the same as or different from that of the substrate 100.

With continued reference to FIGS. 6 and 7, in some embodiments, when the substrate 100 in the isolation region III is etched downward along the trench 404 to form the second trench 103, a portion of the substrate 100 located in the isolation region III is retained to form a first semiconductor material region 104.

In some embodiments, in the device region I, the first trench 101 between the second semiconductor material regions 102 adjacent to each other in the Y direction is provided with a third extension depth H3 in a direction from the first surface 100A of the substrate 100 to the second surface 100B; in the isolation region III, the second trench 103 between the second semiconductor material region 102 and the first semiconductor material region 104 adjacent to each other in the Y direction is provided with a fourth extension depth H4. In addition, in the device region I, the first trench 101 between the dielectric structures 105 adjacent to each other in the Y direction is provided with a fifth extension depth H5; in the isolation region III, the second trench 103 between the dielectric structure 105 and the first isolation region 200 adjacent to each other in the Y direction is provided with a sixth extension depth H6.

In some embodiments, the values of the third extension depth H3 to the sixth extension depth H6 are each less than the first extension depth H1. In some other embodiments, in addition, the values of the third extension depth H3 to the sixth extension depth H6 are each less than the second extension depth H2. In the above embodiments, the third extension depth H3 is less than the fourth extension depth H4, and the fifth extension depth H5 is less than the sixth extension depth H6. In addition, the difference between the third extension depth H3 and the fourth extension depth H4 is controlled within a first predetermined value range; for example, the difference between the third extension depth and the fourth extension depth is between 10 nm and 50 nm. The difference between the fifth extension depth H5 and the sixth extension depth is controlled within a second predetermined value range; for example, the difference between the fifth extension depth and the sixth extension depth is between 10 nm and 50 nm. In some embodiments, while the third extension depth H3 is less than the fourth extension depth H4 and the fifth extension depth H5 is less than the sixth extension depth H6, the third extension depth H3 is less than the fifth extension depth H5 and the fourth extension depth H4 is less than the sixth extension depth H6. In some other embodiments, the fourth extension depth H4 may be equal to or substantially equal to the sixth extension depth H6, and the difference between the fourth extension depth and the sixth extension depth is controlled within 10 nm to 50 nm.

In these embodiments, there is a need to overcome the problem of different etching rates caused by the fact that the material to be etched is not a single component. For example, during the etching process, the objects to be etched include the substrates and the first dielectric layer isolating the substrates, and the substrates and the first dielectric layer exhibit different etching rates. For example, when the substrate is made of silicon and the first dielectric layer is made of silicon oxide, the etching rate of silicon oxide is greater than the etching rate of silicon, resulting in the difference between the fourth extension depth and the sixth extension depth. In addition, since the density of the mask patterns in the device region I is greater than the density of the mask patterns in the isolation region III, the difference between the fourth extension depth and the sixth extension depth may be further magnified according to the etch loading effect, and the excessive difference between the fourth extension depth and the sixth extension depth may bring adverse effects to the subsequent process. Such a phenomenon that the material in the isolation region III is excessively etched may even cause the fourth extension depth H4 and the sixth extension depth H6 to be greater than the first extension depth H1. To address this problem, in these embodiments, when the second trench located between the second semiconductor material region and the first isolation region is formed, a portion of the substrate is retained on the side wall of the second trench to form the first semiconductor material region, and the retained first semiconductor material region can relieve the etch loading effect when the first trenches and the second trench are formed by etching, reduce the fourth extension depth and the sixth extension depth, prevent the fourth extension depth or the sixth extension depth from exceeding the first extension depth, and improve the reliability of the subsequent process.

In some embodiments, the first semiconductor material region 104 is disposed adjacent to the first isolation region 200, as shown in FIG. 7. That is, during the etching process, a portion of the substrate adjacent to the first isolation region 200 is retained, and in this case, the surface of the first semiconductor material region 104 is lower than the surface of the first isolation region 200. In some other embodiments, the first semiconductor material region 104 may be disposed adjacent to the second semiconductor material region; that is, during the etching process, a portion of the substrate adjacent to the device region I is retained.

After step S121, step S122 is performed. The first trenches and the second trench are filled to form an isolation structure in the first trenches, and to form the second isolation region in the second trench.

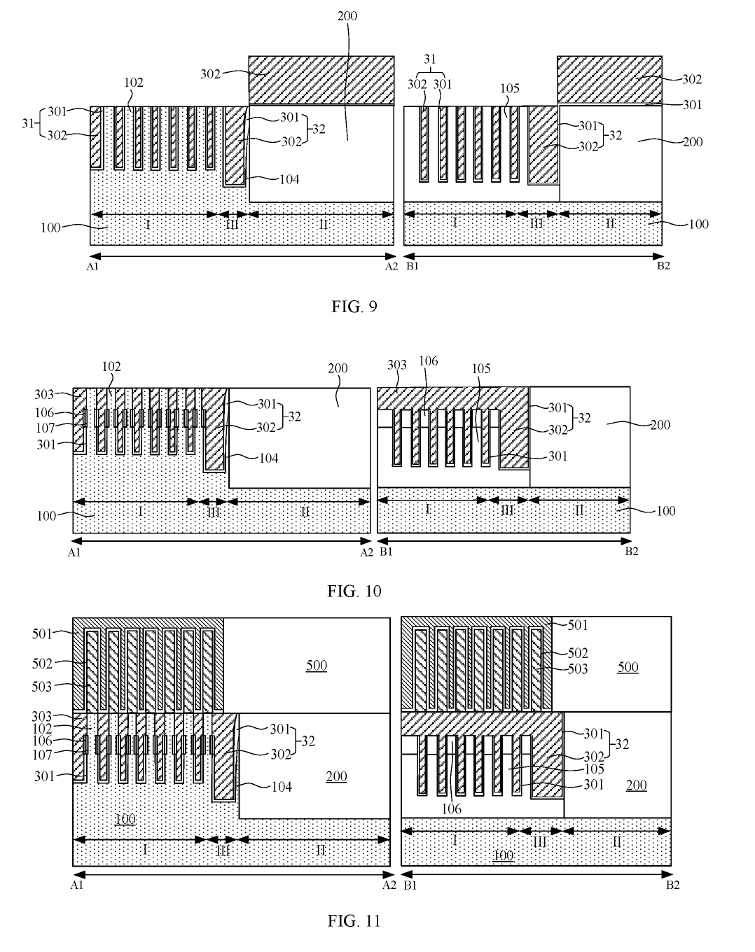

Detailed description is provided below with reference to FIGS. 8 and 9. FIGS. 8 and 9 are schematic cross-sectional views of semiconductor structures according to the embodiments of the present disclosure.

Referring first to FIG. 8, a second dielectric layer 301 and a third dielectric layer 302 are used to fill the first trenches 101 and the second trench 103. The second dielectric layer 301 and the third dielectric layer 302 form a stack structure filling the first trenches 101 and the second trench 103. The second dielectric layer 301 is formed in the first trenches 101 and the second trench 103 before the third dielectric layer 302. In some embodiments, the second dielectric layer 301 and the third dielectric layer 302 are made of different materials. For example, the second dielectric layer 301 may be made of at least one of the dielectrics, such as silicon oxide, silicon nitride, and silicon carbonitride, and the third dielectric layer 302 may be made of another one of the dielectrics, such as silicon oxide, silicon nitride, and silicon carbonitride. As shown in FIG. 8, in addition, the second dielectric layer 301 and the third dielectric layer 302 are both formed on the surface of the first isolation region 200.

With continued reference to FIG. 9, upon filling the first trenches 101 and the second trench 103, the excess second dielectric layer 301 and third dielectric layer 302 are removed, and only portions of the second dielectric layer 301 and third dielectric layer 302 located in the first trenches 101 and the second trench 103 and the second dielectric layer 301 and the third dielectric layer 302 located on the first isolation region 200 are retained. The second dielectric layer 301 and the third dielectric layer 302 retained in the first trenches form an isolation structure 31 located in the first trenches, and the second dielectric layer 301 and the third dielectric layer 302 retained in the second trench form a second isolation region 32 located in the second trench. The isolation structure 31 is formed both between the second semiconductor material regions 102 in the device region I and between the dielectric structures 105 in the device region; the second isolation region 32 is formed both between the second semiconductor material region 102 in the isolation region III and the first isolation region 200 and between the dielectric structure 105 in the isolation region and the first isolation region 200.

After step S122, step S123 is performed. First conductive structures are formed between the isolation structure and the second semiconductor material regions. The first conductive structures, the second semiconductor material regions, and the isolation structure form the device region.

Step S123 is described in detail below with reference to FIG. 10. FIG. 10 is a schematic cross-sectional view of a semiconductor structure according to an embodiment of the present disclosure.

Upon forming the isolation structure and the second isolation region, first conductive structures 106 are formed between the second semiconductor material regions 102 in the device region I. There are a plurality of first conductive structures 106. The plurality of first conductive structures 106 extend in the X direction and wrap around the second semiconductor material regions 102, and the plurality of first conductive structures 106 are spaced apart from each other in the Y direction. In these embodiments, conduction control layers 107 are further disposed between the first conductive structures 106 and the second semiconductor material regions 102, and the conduction control layers 107 wrap the surfaces of the second semiconductor material regions 102. In the above embodiments, the first conductive structures are also formed between the dielectric structures 105 in the device region I.

In some embodiments, the second semiconductor material regions 102, together with corresponding conduction control layers 107 and corresponding first conductive structures 106, form a transistor structure. That is, the second semiconductor material regions 102 may serve as active regions, the conduction control layers 107 may serve as gate dielectric layers, the first conductive structures 106 may serve as gates, and the formed transistor structure may be a gate-all-around (GAA) transistor.

In some embodiments, to form the first conductive structures 106 in the device region I, there is a need to first etch and remove a portion of the second dielectric layer 301 along the first surface of the substrate 100 in the device region I on the basis of FIG. 9, so as to form gaps between the second semiconductor material regions 102 and the third dielectric layer 302. In addition, the dielectric structures 105 and the second dielectric layer 301 on the B1-B2 line are also partially removed, so as to form a gap in the third dielectric layer 302 on the B1-B2 line. Upon forming the above gaps, a dielectric layer is backfilled in the gaps, thereby forming a dielectric structure 303 shown in FIG. 10. In this case, the dielectric structure 303, the second dielectric layer 301, and the third dielectric layer 302 form the isolation structure 31 of the first conductive structure 106. In addition, the dielectric structure 303 is also formed in the second isolation region 32. In some embodiments, the dielectric structure 303 and the third dielectric layer 302 are made of the same material, for example, one of silicon oxide, silicon nitride, and silicon carbonitride. In this case, in the second isolation region 32 and the isolation structure 31, the dielectric structure 303 and the third dielectric layer 302 may not be directly distinguished from each other, and there is no clear boundary between them.

In some embodiments, when the dielectric structure 303 is backfilled in these gaps, the gaps on the A1-A2 line are completely filled, and the gap in the third dielectric layer 302 on the B1-B2 line is partially filled. That is, the gaps on the B1-B2 line are only partially filled with the dielectric structure 303. The unfilled gaps are used in subsequent steps as windows to further etch downward the second dielectric layer 301 and the dielectric structures 105, thereby providing space for the subsequently formed first conductive structures 106.

With continued reference to FIG. 10, upon forming the first conductive structures 106, the device region I in this case includes the first conductive structures 106, the second semiconductor material regions 102, and the isolation structure isolating the second semiconductor material regions 102 and the first conductive structures 106. The isolation structure in the device region I includes the second dielectric layer 301, the third dielectric layer 302, and the dielectric structure 303. Since the third dielectric layer 302 and the dielectric structure 303 in the device region I are made of the same material, the third dielectric layer 302 and the dielectric structure 303 are both identified by the dielectric structure 303 in FIG. 10.

With continued reference to FIGS. 7 and 10, the isolation structure is formed by filling the first trenches 101 and the second isolation region is formed by filling the second trench 103. Therefore, in some embodiments, in the direction from the first surface 100A of the substrate 100 to the second surface 100B, i.e., a direction perpendicular to the substrate 100, the extension depth of the formed isolation structure is less than the extension depth of the second isolation region 32 or less than the extension depth of the first isolation region 200. In some embodiments, the extension depth of the isolation structure is less than both the extension depth of the first isolation region 200 and the extension depth of the second isolation region 32.

With continued reference to FIG. 10, in some embodiments, upon forming the isolation structure, the second isolation region, and the first conductive structures, the surface of the semiconductor structure is planarized to remove excess materials on the surfaces of the regions, so as to keep the surfaces of the device region I, the isolation region II, and the isolation region III flush or substantially flush with each other.

In these embodiments, the surface of the first semiconductor material region 104 adjacent to the first surface 100A of the substrate 100 is covered by the second isolation region 32; that is, the top surface of the first semiconductor material region 104 is not exposed by the second isolation region 32. In some other embodiments, the top surface of the first semiconductor material region 104 may also be exposed by the second isolation region 32; that is, the top surface of the first semiconductor material region 104 is coplanar with the top surfaces of the isolation structure in the device region I, the second isolation region 32, and the first isolation region 200.

In some embodiments, upon forming the isolation structure, the second isolation region, and the first conductive structures, the method further includes forming a charge storage structure in the device region I.

The process of forming the charge storage structure is described in detail below with reference to FIG. 11. FIG. 11 is a schematic cross-sectional view of a semiconductor structure according to an embodiment of the present disclosure. A lower electrode 503, a dielectric layer 502, and an upper electrode 501 are deposited on the surfaces of the formed isolation structure and second isolation region. The lower electrode 503 is in electrical contact with the second semiconductor material regions 102 in the device region I, the dielectric layer 502 covers the surface of the lower electrode 503, the upper electrode 501 covers the surface of the dielectric layer 502, and the upper electrode 501, the lower electrode 503, and the dielectric layer 502 form a charge storage structure. The first conductive structures 106 in the device region I control whether the second semiconductor material regions 102 are connected to the charge storage structure, and the first conductive structures 106 may serve as word lines of a DRAM storage structure. The second semiconductor material regions 102 are responsible for providing transport channels for charges in the charge storage structure and supplying charges, and the second semiconductor material regions 102 may serve as active regions of a DRAM transistor.

In some embodiments, referring to FIG. 11, an isolation dielectric layer 500 is formed on the first isolation region 200 and the second isolation region 32, and the isolation dielectric layer 500 is configured to isolate the charge storage structure from a surrounding environment. The isolation dielectric layer 500 and the first isolation region 200 may be made of the same material or different materials. For example, the isolation dielectric layer 500 may be made of silicon oxide, or one or more of silicon nitride and silicon carbonitride.

In some embodiments, upon performing step S122, step S123 is further performed. Step S123 includes forming second conductive structures in the device region, which includes: thinning the second surface of the substrate, such that a portion of the substrate in the device region is retained and the substrate in the first isolation region and the second isolation region is removed; and forming the second conductive structures on the surface of the retained substrate in the device region, the second conductive structures being connected to the second semiconductor material regions.

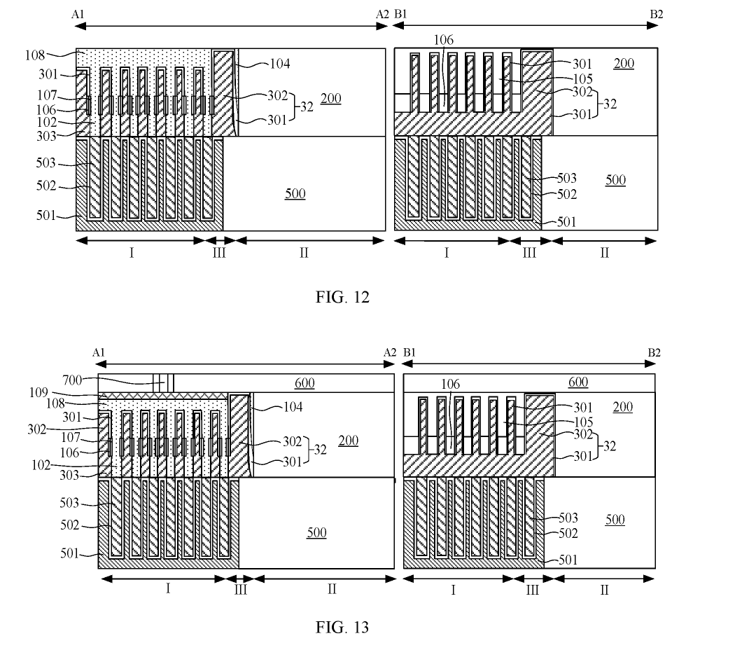

Step S123 is described in detail below with reference to FIGS. 12 and 13. FIGS. 12 and 13 are schematic cross-sectional views of a semiconductor structure according to an embodiment of the present disclosure. Upon forming the charge storage structure, the semiconductor structure is turned over by 180°, and the second surface 100B of the substrate 100 is used as a surface to be processed to thin the substrate 100. During this process, the substrate 100 on the A1-A2 line, i.e., the bottom of the second semiconductor material region 102, is partially removed, and the retained portion of the substrate is marked as the substrate 108. In addition, the bottom surface of the first semiconductor material region 104 in the second isolation region 32 is also partially removed, and the substrate on the first isolation region 200 and the substrate 100 on the B1-B2 line are also removed synchronously until the dielectric structures 105 are exposed. In some embodiments, during the above thinning process, the surface of the first isolation region 200 is used as a thinning stop region. That is, when the first isolation region 200 is contacted during thinning, the thinning process is stopped. In the above embodiments, the second isolation region 32 may not be thinned; for example, the thinning process is allowed to stop at the second dielectric layer 301. The second isolation region 32 may also be thinned; for example, the thinning process is allowed to stop at the third dielectric layer 302.

During the thinning process of the semiconductor structure, in the foregoing process steps, the difference between the extension depth of the isolation structure in the device region I and/or the extension depth of the second isolation region and the extension depth of the first isolation region is reduced by retaining a portion of the first semiconductor material region in the second isolation region, such that the second isolation region and the isolation structure are prevented from being provided with deeper extension depths in a direction facing the second surface of the substrate. If the extension depths of the second isolation region and the isolation structure are excessively deep, during the thinning of the substrate, the second isolation region 32 and the isolation structure may be exposed before the first isolation region 200 and even the substrate 100 as the thinning proceeds, and the substrate 100 and the dielectric structures 105 are thinned after the second isolation region and the isolation structure are further thinned. As a result, the dielectric in the isolation structure and/or the second isolation region needs to be further thinned during the thinning process, which introduces serious risks to the thinning process, not only increasing the cost of the thinning process but also degrading the process yield. For example, when the first isolation region 200 is used as a thinning stop region only the substrate 100 in the device region I, the isolation region II, and the isolation region III needs to be thinned. This is because, in this case, the extension depths of the isolation structure, the second isolation region 32, and the like do not exceed the extension depth of the first isolation region 200. The isolation structure, the second isolation region 32, and the like therefore do not adversely affect the thinning process, thereby improving the stability of the thinning process. Conversely, when the extension depths of the isolation structure, the second isolation region 32, and the like exceed the extension depth of the first isolation region 200, during the thinning process, the substrate 100, the second dielectric layer 301, and even the third dielectric layer 302 need to be simultaneously thinned. During the thinning process in this case, there is a need to balance the thinning uniformity of the silicon substrate, the second dielectric layer, and the third dielectric layer, which greatly increases the difficulty of the process.

In the above embodiments, the thinning process may be carried out using a chemical mechanical polishing process or other surface planarization processes.

With continued reference to FIG. 13, the second conductive structures 109 are formed on the thinned substrate 108 in the device region I, and the second conductive structures 109 are in direct contact with the substrate 108. The process of forming the second conductive structures 109 may adopt a conductive thin film deposition process. Upon depositing the conductive thin film, an annealing process may be performed to achieve an efficient electrical connection between the second conductive structures 109 and the substrate 108; for example, an ohmic contact between the second conductive structures 109 and the substrate 108 is achieved by annealing.

In some embodiments, the second conductive structures 109 are formed on the surface of the substrate 108 corresponding to the second semiconductor material regions 102, and the second conductive structures 109 are not disposed in the regions between the second semiconductor material regions 102 adjacent to each other in the X direction, i.e., in the regions where the dielectric structures 105 are located. The second conductive structures 109 are arranged perpendicular to the first conductive structures 106, the first conductive structures 106 are connected to a plurality of second semiconductor material regions 102 extending in the X direction, the second conductive structures 109 are connected to a plurality of second semiconductor material regions 102 extending in the Y direction, the second conductive structures 109 are configured to perform read/write operations on the capacitors in the charge storage structure, and the second conductive structures 109 may serve as bit lines of the DRAM storage structure. The number of the second conductive structures 109 may be the same as that of the first conductive structures 106, and there may be a plurality of second conductive structures. The first conductive structures 106 extend in the X direction and are spaced apart in the Y direction, and the second conductive structures 109 extend in the Y direction and are spaced apart in the X direction.

In some embodiments, the first conductive structure 106 may be made of one or more metals, such as titanium, tungsten, cobalt, nickel, platinum, and gold, or silicides thereof. The second conductive structure 109 may be made of one or more metals, such as titanium, tungsten, cobalt, nickel, platinum, and gold, or silicides thereof.

With continued reference to FIG. 13, in some embodiments, upon forming the second conductive structures 109, an isolation dielectric layer 600 is deposited on the surface of the semiconductor structure, and contact pads 700 interconnected with the second conductive structures 109 in the device region I are formed in the isolation dielectric layer 600. The second conductive structures 109 are interconnected with other functional units through the contact pads 700.

In some embodiments, during the substrate thinning process, one surface of the first semiconductor material region 104 is also exposed. Therefore, the second conductive structures 109 may also be formed on the surface of the first semiconductor material region 104.

Some embodiments of the present disclosure further provide a semiconductor structure. The semiconductor structure includes: a substrate, a first isolation region, and a second isolation region. The substrate is provided with a device region. The second isolation region is disposed between the device region and the first isolation region; the second isolation region is further provided with a first semiconductor material region, and the first semiconductor material region is disposed adjacent to the first isolation region.

For a schematic view of a structure of a semiconductor structure, reference may be made to FIG. 13. As shown in the figure, the semiconductor structure includes a device region I, an isolation region II, and an isolation region III. The isolation region III is disposed between the device region I and the isolation region II. The device region I is provided with a substrate 108, and the substrate 108 is a semiconductor substrate. The isolation region II is provided with a first isolation region 200, the isolation region III is provided with a second isolation region 32, the second isolation region 32 is further provided with a first semiconductor material region 104, and the first semiconductor material region 104 may be disposed adjacent to the first isolation region 200 or adjacent to the device region I. FIG. 13 illustrates a case where the first semiconductor material region 104 is disposed adjacent to the first isolation region 200.

In some embodiments, the first semiconductor material region 104 may be a portion of the substrate 108 or made of the same material as the substrate 108.

In some embodiments, the first semiconductor material region 104 is formed between the second isolation region 32 and the first isolation region 200 adjacent to each other on the A1-A2 line, and the first semiconductor material region 104 is not formed between the second isolation region 32 and the first isolation region 200 adjacent to each other on the B1-B2 line. At least one surface of the first semiconductor material region 104 is not exposed by the second isolation region 32; that is, at least one surface of the first semiconductor material region 104 is not exposed on the surface of the isolation region III. For the positions of the line A1-A2 and the line B1-B2 in the semiconductor structure, reference may be made to FIG. 3 and the descriptions of the corresponding drawings.

In the semiconductor structure according to the embodiments of the present disclosure, by retaining a portion of the semiconductor material region in the isolation region adjacent to the device region, dimensional variations between the device region and the isolation region caused by differences in pattern density are compensated, thereby achieving a semiconductor structure with higher yield.

With continued reference to FIG. 13, the device region I of the semiconductor structure includes a plurality of second semiconductor material regions 102 spaced apart from each other in an X direction and a Y direction, first conductive structures 106 disposed corresponding to the second semiconductor material regions 102, and an isolation structure (301+302+303) isolating the first conductive structures. The second semiconductor material regions 102 arranged in the Y direction share the substrate 108, and dielectric structures 105 are disposed between the second semiconductor material regions 102 arranged in the X direction. The dielectric structures are configured to isolate the second semiconductor material regions 102 in the X direction. The first conductive structures 106 extend in the X direction and are isolated from each other in the Y direction, each first conductive structure 106 extending in the X direction is correspondingly connected to each row of the second semiconductor material regions 102 arranged in the X direction, and the isolation structure is disposed between the second semiconductor material regions 102 adjacent to each other in the X direction and the Y direction and between the first conductive structures 106 adjacent to each other in the Y direction, so as to achieve the isolation of the second semiconductor material regions 102 and the isolation of the first conductive structures 106.

In some embodiments, the first semiconductor material region 104 and the second semiconductor material region 102 are both formed from the substrate 108 or made of the same material as the substrate 108.

In some embodiments, the isolation structure includes a second dielectric layer 301 and a dielectric structure 303. The isolation structure proximal to the substrate 108 includes a stack structure composed of the second dielectric layer 301 and a third dielectric layer 302, and the isolation structure distal to the substrate 108 includes a composite structure composed of the third dielectric layer 302 and the dielectric structure 303. The second dielectric layer 301 and the third dielectric layer 302 may be made of different dielectric materials. For example, the second dielectric layer 301 is made of silicon oxide, and the third dielectric layer 302 is made of silicon nitride, or vice versa. The third dielectric layer 302 and the dielectric structure 303 may be made of the same dielectric material; for example, the third dielectric layer and the dielectric structure are both made of a dielectric material, such as silicon nitride, silicon oxide, or the like.

In some embodiments, the first isolation region 200 may include at least one isolation material, such as silicon nitride or silicon oxide. In some other embodiments, the first isolation region 200 may also include two or more types of isolation materials to achieve a better isolation effect.

In some embodiments, the second isolation region 32 includes at least two isolation materials, for example, a stack structure composed of the second dielectric layer 301 and the third dielectric layer 302.

In some embodiments, in a direction perpendicular to the substrate 108, i.e., in a direction perpendicular to the X direction and the Y direction, the extension depth of the isolation structure is less than the extension depth of the first isolation region 200 or the extension depth of the second isolation region 32, and the extension depth of the second isolation region 32 is not greater than the extension depth of the first isolation region 200. The difference in extension depths between the isolation structure and the first isolation region or the second isolation region in the semiconductor structure obtained according to the embodiments of the present disclosure can be further reduced, thereby preventing the extension depth value of the second isolation region from being excessively large, and thus avoiding affecting the performance of the semiconductor structure.

In some embodiments, the device region I of the semiconductor structure further includes second conductive structures 109, and the second conductive structures 109 are disposed corresponding to a plurality of second semiconductor material regions 102. There are a plurality of second conductive structures 109, and the second conductive structures 109 extend in the Y direction and are spaced apart in the X direction. The second conductive structures 109 are arranged perpendicular to the first conductive structures 106. The second conductive structures 109 are connected to the second semiconductor material regions 102 arranged in the Y direction, respectively. The second conductive structures 109 in the row in the X direction are electrically isolated from each other through the dielectric structures 105. The first conductive structures 106 and the second conductive structures 109 are isolated by an isolation structure, for example, by the second dielectric layer 301.

In the semiconductor structure according to the above embodiments, the first conductive structures 106 in the device region I may serve as word lines, the second conductive structures 109 in the device region may serve as bit lines, and the second semiconductor material regions 102 in the device region may serve as active regions constituting a transistor. The device region I further includes conduction control layers 107, and the conduction control layers 107 may serve as gate dielectric layers of the transistor.

In some embodiments, the device region I further includes a charge storage structure. The charge storage structure is composed of an upper electrode 501, a dielectric layer 502, and a lower electrode 503. Charge storage structures are connected to corresponding second semiconductor material regions 102. The charge storage structures may serve as DRAM capacitors.

In some embodiments, the semiconductor structure further includes an isolation dielectric layer 500 disposed on the first isolation region 200 and/or the second isolation region 32, and the isolation dielectric layer 500 is further disposed at a periphery of the charge storage structure. The isolation dielectric layer is configured to isolate the charge storage structure.

In the above embodiments, the first conductive structure 106 is disposed between the second conductive structure 109 and a charge storage structure.

In some embodiments, the semiconductor structure further includes an isolation dielectric layer 600. The isolation dielectric layer 600 is disposed on the device region I, the isolation region II, and the isolation region III, and covers the second conductive structures 109, the dielectric structures 105, the first isolation region 200, and the second isolation region 32. The isolation dielectric layer 600 is provided with contact pads 700. The contact pads are configured to achieve the interconnection between the second conductive structures 109 and other functional units.

In some embodiments, the surface of the second conductive structure 109 is not lower than the surfaces of the first isolation region 200 and the second isolation region 32. The surface of the second conductive structure 109 herein refers to the surface of the second conductive structure 109 distal to the substrate 108, and the surfaces of the first isolation region 200 and the second isolation region 32 also refer to surfaces in the same direction.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

1. A semiconductor structure, comprising:
a substrate, the substrate being provided with a device region;
a first isolation region; and
a second isolation region, the second isolation region being disposed between the device region and the first isolation region;
the second isolation region being further provided with a first semiconductor material region, and the first semiconductor material region being disposed adjacent to the first isolation region.

2. The semiconductor structure according to claim 1, wherein the device region comprises a plurality of second semiconductor material regions spaced apart, first conductive structures disposed corresponding to the plurality of second semiconductor material regions, and an isolation structure isolating the first conductive structures, and in a direction perpendicular to the substrate, an extension depth of the isolation structure is less than an extension depth of the first isolation region or an extension depth of the second isolation region, and the extension depth of the second isolation region is not greater than the extension depth of the first isolation region.

3. The semiconductor structure according to claim 2, wherein the device region further comprises second conductive structures, the second conductive structures are disposed corresponding to the plurality of second semiconductor material regions, the isolation structure is further disposed between the first conductive structures and the second conductive structures, and the second conductive structures are connected to corresponding second semiconductor material regions.

4. The semiconductor structure according to claim 3, wherein a surface of each second conductive structure is not lower than surfaces of the first isolation region and the second isolation region.

5. The semiconductor structure according to claim 1, wherein the first isolation region comprises at least one isolation material, the second isolation region comprises at least two isolation materials, and at least one of the at least two isolation materials in the second isolation region is different from the at least one isolation material in the first isolation region.

6. The semiconductor structure according to claim 1, wherein at least one surface of the first semiconductor material region is not exposed by a surface of the second isolation region.

7. The semiconductor structure according to claim 1, wherein the substrate is provided with a first surface and a second surface disposed opposite to the first surface, and in a direction adjacent to the first surface, a surface of the first semiconductor material region is lower than a surface of the second isolation region.

8. The semiconductor structure according to claim 1, wherein the substrate is provided with a first surface and a second surface disposed opposite to the first surface, the first isolation region extends from the first surface to the second surface, and in a direction adjacent to the first surface, a surface of the first semiconductor material region is lower than a surface of the first isolation region.

9. The semiconductor structure according to claim 2, wherein the isolation structure comprises at least two isolation materials, each of the at least two isolation materials in the isolation structure is the same as an isolation material in the second isolation region, and at least one of the at least two isolation materials in the isolation structure is different from an isolation material in the first isolation region.

10. The semiconductor structure according to claim 1, wherein the substrate and the first semiconductor material region are of a same structure.

11. A method for forming a semiconductor structure, comprising:
providing a substrate, and patterning the substrate to form a first isolation region in the substrate; and
patterning the substrate to form a device region and a second isolation region in the substrate, the second isolation region being disposed between the device region and the first isolation region;
wherein when the substrate is patterned to form the second isolation region, a portion of the substrate located in the second isolation region is retained to form a first semiconductor material region, and the first semiconductor material region is disposed adjacent to the first isolation region.

12. The method according to claim 11, wherein the substrate is provided with a first surface and a second surface, and the first surface is disposed opposite to the second surface; patterning the substrate to form the device region and the second isolation region in the substrate comprises:
patterning the first surface of the substrate to form a plurality of first trenches and a second trench in the substrate, the substrate being divided by the plurality of first trenches to form a plurality of second semiconductor material regions spaced apart;
filling the plurality of first trenches and the second trench to form an isolation structure in the first trenches, and to form the second isolation region in the second trench; and
forming first conductive structures between the isolation structure and the plurality of second semiconductor material regions, the first conductive structures, the plurality of second semiconductor material regions, and the isolation structure forming the device region; wherein
in a direction perpendicular to the substrate, an extension depth of the isolation structure is less than an extension depth of the second isolation region or an extension depth of the first isolation region, and the extension depth of the second isolation region is not greater than the extension depth of the first isolation region.

13. The method according to claim 12, further comprising forming second conductive structures in the device region, wherein forming the second conductive structures in the device region comprises:
thinning the second surface of the substrate, such that a portion of the substrate in the device region is retained and the substrate in the first isolation region and the second isolation region is removed; and
forming the second conductive structures on a surface of the retained substrate in the device region, the second conductive structures being connected to corresponding second semiconductor material regions.

14. The method according to claim 13, wherein during the thinning of the second surface of the substrate, the first isolation region is used as a thinning stop region.

15. The method according to claim 13, wherein during the thinning of the second surface of the substrate, the second isolation region is not thinned, and a surface of the first semiconductor material region is exposed by a surface of the second isolation region.

16. The semiconductor structure according to claim 1, wherein the first semiconductor material region is a portion of the substrate.

17. The semiconductor structure according to claim 2, wherein the second semiconductor material region is a portion of the substrate.
